(19) United States
(12) Patent Application Publication
(10) Pub. No.: US 2025/0364654 A1
(43) Pub. Date: Nov. 27, 2025

(54) BEAM ASSEMBLY FOR A BATTERY PACK

(71) Applicant: Ford Global Technologies, LLC, Dearborn, MI (US)

(72) Inventors: Fei Gao, Nanjing (CN); Bin Yin, Nanjing (CN); Freddy Wu, Nanjing (CN); Larry Wang, Nanjing (CN)

(21) Appl. No.: 19/042,757

(22) Filed: Jan. 31, 2025

(30) Foreign Application Priority Data
Feb. 22, 2024 (CN) 2024102010995

(51) Int. Cl. H01M 50/204; H01M 50/249; H01M 50/271; H01M 50/289; H05K 7/20

(52) U.S. Cl. CPC H01M 50/204; H01M 50/249; H01M 50/271; H01M 50/289; H05K 7/20918; H01M 2220/20

(57) ABSTRACT

A beam assembly for a battery pack includes a push beam that extends along a first direction and is connected to a tray of the battery pack; a support member that extends along a second direction and connects the at least one push beam to the tray; and a side rail that extends along the second direction and is connected to the at least one push beam from an end of the at least one push beam. The side rail can have a plurality of cooling plate mounting portions spaced apart from each other. A battery pack can include the beam assembly.

### CROSS-REFERENCE TO RELATED APPLICATIONS

This disclosure claims priority to Chinese Patent Application No. 2024102010995, which was filed on 22 Feb. 2024 and is incorporated herein by reference in its entirety.

### TECHNICAL FIELD

The present disclosure generally relates to the field of vehicle batteries and, more specifically, to a beam assembly for a battery pack and a battery pack.

### BACKGROUND

With the development of consumer demand for fuel conservation and environmental protection in current market, various new energy vehicles, including but not limited to pure electric vehicles (BEVs), hybrid electric vehicles (HEVs), and plug-in hybrid electric vehicles (PHEVs), are becoming increasingly popular. These new energy vehicles will become one of the future development trends in automotive industry due to their advantages in fuel conservation, environmental friendliness, and economy.

Most new energy vehicles have battery packs. The battery pack is typically composed of multiple battery arrays to provide power to an electric motor of the vehicle, which in turn provides driving power to the vehicle either alone or in conjunction with a vehicle engine.

The battery pack usually contains multiple battery modules. With the increasing demand for range and fast charging of the new energy vehicle, charging voltage and battery capacity of the battery pack of the new energy vehicle will increase, and the number of the battery modules will also increase. The possible expansion of the battery and the resulting expansion force can affect stability of fixed structures of the battery, such as end plates, side plates, and other fixing components of the battery array, thereby posing challenges to the fixation and packaging of the battery.

### SUMMARY

The present disclosure summarizes various aspects of embodiments and should not be used to limit the claims. Other implementations are contemplated in accordance with the techniques described herein, as will be apparent upon examination of the following drawings and detailed description, and such implementations are intended to be within the scope of this application.

According to one aspect of the present disclosure, there is provided a beam assembly for a battery pack, comprising:
a push beam that extends along a first direction and is connected to a tray of the battery pack;
a support member that extends along a second direction and connects the push beam to the tray; and
a side rail that extends along the second direction and is connected to the push beam from an end of the push beam, the side rail having multiple cooling plate mounting portions spaced apart.

In an embodiment, the push beam comprises a first push beam and a second push beam that are spaced apart and respectively connected at their ends to the tray, and a receiving portion is formed between the first push beam and the second push beam.

In another embodiment, the support member comprises a first support member and a second support member that respectively connect the push beam to the tray in the second direction.

In yet another embodiment, the push beam further comprises:
a third push beam that extends along the first direction and is spaced apart from the first push beam and the second push beam, the third push beam being connected at its ends to the tray in the first direction and dividing the receiving portion into a first receiving portion and a second receiving portion.

In yet another embodiment, the side rail comprises a first side rail and a second side rail that are spaced apart, extend along the second direction, and are respectively connected to the first push beam and the second push beam from ends of the first push beam and the second push beam.

In yet another embodiment, the cooling plate mounting portions are mounting slots, multiple mounting slots are recessed along the first direction and spaced apart along the second direction, and the multiple mounting slots on the first side rail and the second side rail are arranged opposite to each other.

In yet another embodiment, the beam assembly further comprises: a pull beam that extends along the second direction and is respectively connected to the first push beam and the second push beam.

In yet another embodiment, the support member is spaced apart from the pull beam in a third direction, which is a height direction.

In yet another embodiment, the pull beam comprises a first pull beam and a second pull beam, and wherein the first support member and the second support member are spaced apart from the first pull beam and the second pull beam along the first direction.

According to another aspect of the present invention, there is also provided a battery pack, comprising:
a tray comprising a bottom plate and a frame;
a beam assembly comprising:
a push beam that extends along a first direction and is connected to the tray of the battery pack;
a support member that extends along a second direction and connects the push beam to the tray;
a side rail that extends along the second direction and is connected to the push beam from an end of the push beam, the side rail having multiple cooling plate mounting portions spaced apart; and
a cover plate that is sealingly connected to the tray.

In yet another embodiment, the push beam comprises a first push beam and a second push beam that are spaced apart and respectively connected at their ends to the tray, and a receiving portion is formed between the first push beam and the second push beam to accommodate batteries.

In yet another embodiment, the side rail comprises a first side rail and a second side rail that are spaced apart, extend along the second direction, and are respectively connected to the first push beam and the second push beam from ends of the first push beam and the second push beam.

In yet another embodiment, the cooling plate mounting portions are mounting slots, multiple mounting slots are recessed along the first direction and spaced apart along the second direction, and the multiple mounting slots on the first side rail and the second side rail are arranged opposite to each other;
multiple cooling plates are installed along the first direction through the multiple mounting slots and abut multiple batteries along the second direction.

In yet another embodiment, the battery pack further comprises a cooling pipe that extends along the second direction between one end of the push beam and the tray and comprises an inlet pipe having multiple inlet openings and an outlet pipe having multiple outlet openings.

In yet another embodiment, each of the multiple inlet openings of the inlet pipe is respectively connected to an inlet manifold of each cooling plate, and each of the multiple outlet openings of the outlet pipe is respectively connected to an outlet manifold of each cooling plate; and the cooling plate has multiple paths extending along the first direction and a third direction, which is a height direction.

In yet another embodiment, the inlet pipe and the outlet pipe are spaced apart and parallel to each other in the third direction, and the inlet pipe is arranged below the outlet pipe.

In yet another embodiment, the battery pack further comprises: a pull beam that extends along the second direction and is respectively connected to the first push beam and the second push beam; and the supporting member is spaced apart from the pull beam in a third direction, which is a height direction.

In yet another embodiment, the pull beam has a lower surface that abuts the bottom plate of the tray and is connected to the bottom plate.

In yet another embodiment, the cover plate comprises an opening that is covered and sealed by an electrical housing, and the electrical housing accommodates electrical components of the battery pack and has a detachable window.

According to yet another aspect of the present invention, there is also provided a battery pack, comprising:
a tray comprising a bottom plate and a frame;
a beam assembly comprising:
a push beam comprising a first push beam and a second push beam that is spaced apart, extend along a first direction and is connected to the tray of the battery pack to form a receiving portion between the first push beam and the second push beam for accommodating multiple batteries stacked along a second direction;
a support member comprising a first support member and a second support member that extend along the second direction and respectively connect the first push beam and the second push beam to the tray;
a side rail comprising a first side rail and a second side rail that is spaced apart, extend along the second direction, and is connected to the first push beam and the second push beam from ends of the first push beam and the second push beam;
wherein the side rail has multiple cooling plate mounting portions spaced apart, multiple cooling plates are installed along the first direction through the multiple mounting slots and abut multiple batteries along the second direction; and
a cover plate that is sealingly connected to the tray;
wherein the cover plate comprises an opening that is covered and sealed by an electrical housing, and the electrical housing accommodates electrical components of the battery pack and has a detachable window.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE FIGURES

For a better understanding of the present disclosure, reference may be made to embodiments shown in the following drawings. The components in the drawings are not necessarily to scale and related elements may be omitted, or in some instances proportions may have been exaggerated, so as to emphasize and clearly illustrate the novel features described herein. In addition, system components can be variously arranged, as known in the art. Further in the figures, like referenced numerals refer to like parts throughout the different figures.

FIG. 1 is a structural schematic diagram of a beam assembly for a battery pack according to an exemplary embodiment of the present disclosure.

FIG. 2 is a structural schematic diagram of the beam assembly for a battery pack according to an exemplary embodiment fixed to a tray of the battery pack.

FIG. 3 is a schematic sectional view of the beam assembly for a battery pack according to an exemplary embodiment of the present disclosure.

FIG. 4 is a structural schematic diagram of a battery pack with a cover plate removed according to an exemplary embodiment of the present disclosure.

FIG. 5 is a structural schematic diagram of multiple cooling plates assembled with coolant inlet and outlet pipes according to an exemplary embodiment of the present disclosure.

FIG. 6 is a structural schematic diagram of the beam structure according to an embodiment of the present disclosure assembled with the cooling plates;

FIG. 7 is a schematic sectional view of the internal structure and fluid path of the cooling plate according to an embodiment of the present disclosure;

FIG. 8 is a structural schematic diagram of the battery pack according to an embodiment of the present disclosure; and

FIG. 9 is another structural schematic diagram of the battery pack according to an embodiment of the present disclosure.

### DETAILED DESCRIPTION

Embodiments of the present disclosure are described below. However, it is to be understood that the disclosed embodiments are merely examples and other embodiments may take various and alternative forms. The figures are not necessarily to scale. Some features may be exaggerated or minimized to show details of particular components. Therefore, specific structural and functional details disclosed herein are not to be interpreted as limiting, but merely as a representative basis for teaching one skilled in the art to variously employ the present disclosure. As will be understood by those of ordinary skill in the art, various features shown and described with reference to any one figure may be combined with features shown in one or more other figures to produce embodiments not expressly shown or described. The combinations of features shown herein provide representative embodiments for typical applications. However, various combinations and modifications of the features consistent with the teachings of the present disclosure may be desired for certain particular applications or implementations.

In order to facilitate stability of the battery pack after the battery being fixed and packaged, suppress battery expansion to a certain extent, and simplify the packaging process, exemplary embodiments of the present disclosure provide a beam assembly for a battery pack.

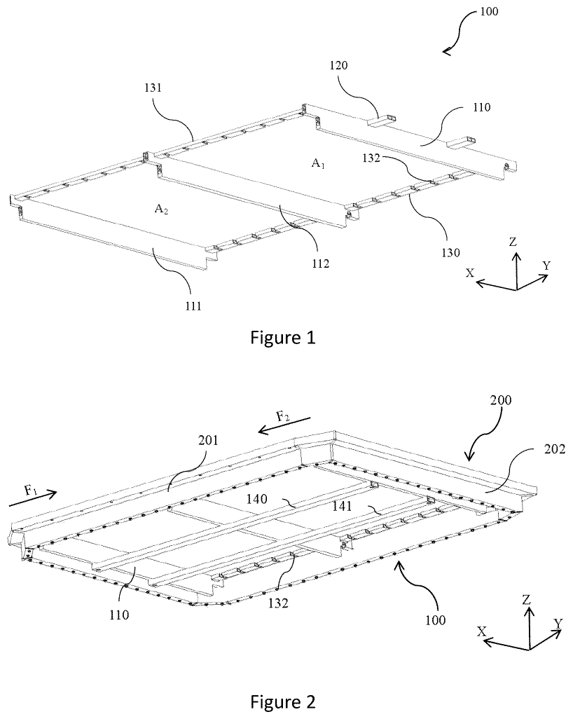

As shown in FIG. 1, in a non-limiting embodiment of the present invention, a beam assembly 100 for a battery pack is illustrated. The beam assembly 100 includes a first push beam 110, a second push beam 111, and a third push beam 112 that extend in a first direction X and are arranged opposite to each other. Combined with FIG. 2, the first push beam 110, the second push beam 111, and the third push beam 112 are respectively connected to side plates 201 of a tray 200 of the battery pack at their two ends in the first direction X. The connection here can be made through one or more of the following methods, including but not limited to welding, bonding, or the use of fasteners. In addition, “end” in the description of the present disclosure refers to the portion of a structural component located on an outer side in a length direction, with a length of one-fifth of the overall length of the structural component in this embodiment. It can be understood that in other embodiments, the end may also have a length between one-quarter and one tenth of the overall length of the structural component.

By connecting the first push beam 110, the second push beam 111, and the third push beam 112 to the side plates 201 of the tray 200, a first receiving portion A₁ for accommodating batteries is formed between the first push beam 110 and the third push beam 112, and a second receiving portion A₂ for accommodating batteries is formed between the second push beam 111 and the third push beam 112. By providing the third push beam 112, the receiving portion between the first push beam 110 and the second push beam 111 is separated, thereby reducing the number of batteries clamped between each two push beams and enhancing structural stability. However, it can be understood that in another embodiment of the present invention, the technical effect of clamping and fixing the batteries can also be achieved by using only the first push beam 110 and the second push beam 111.

Continuing with reference to FIGS. 1 and 2, the beam assembly 100 also includes a first support member 120 and a second support member (not shown in the figure). Wherein, the first support member 120 and the second support member both extend along a second direction Y and are respectively connected to the first push beam 110 and the second push beam 111, as well as connect the first push beam 110 and the second push beam 111 to opposite end plates 202 of the tray 200. In another embodiment, the first support member and the second support member can also be used on the same side to support either the first push beam or the second push beam. In this embodiment, the first support member 120 and the second support member are support beam structures. It can be understood that in various embodiments of the present disclosure, other support structures, for example rigid structures with a length in the second direction Y, such as protrusions extending from the push beam or the end plate, can also serve as support members connecting the push beam to the end plate.

Continuing with reference to FIG. 1, the beam assembly 100 also includes a first side rail 130 and a second side rail 131 extending along the second direction Y. Each of the first side rail 130 and the second side rail 131 is connected to the ends of the first push beam 110, the second push beam 111, and the third push beam 112, respectively, to form a stable frame structure. The first side rail 130 and the second side rail 131 are provided with multiple mounting portions spaced apart along the second direction Y. In this embodiment, the mounting portions are mounting slots 132. The mounting slots 132 on the first side rail 130 and the second side rail 131 are arranged opposite to each other, so that cooling plates can be fixed between them. It can be understood that in various embodiments of the present invention, the mounting portions can also be other fixed structures, including but not limited to fixed components such as clamps, bolts, etc.

In another embodiment, the beam assembly may only include one push beam, a first support member, and one side rail, wherein the push beam extends along the first direction and is connected to the side plates of the tray of the battery pack in the first direction, the support member extends along the second direction and connects the push beam to the end plate of the tray in the second direction, and the side rail extends along the second direction and is connected to the push beam from the end of the push beam, and the side rail has multiple mounting portions spaced apart. With this arrangement, a receiving portion for batteries is formed between the push beam and the end plates of the tray on the opposite side, and the cooling plate is also installed only through the mounting portion on one side rail.

Referring to the embodiment shown in FIG. 2, the beam assembly 100 further includes a first pull beam 140 and a second pull beam 141 extending along the second direction Y. The first pull beam 140 and the second pull beam 141 have two ends in the second direction Y that are respectively connected to lower surfaces of the first push beam 110 and the second push beam 111 in a third direction Z, and a main body portion that is also connected to a lower surface of the third push beam 112.

In another embodiment of the present disclosure, the beam assembly may only have one pull beam. Technicians in this field can understand that the number of the pull beams in the above embodiments is only an example and can be provided according to the needs of stable packaging of the battery pack.

Combining FIG. 1 and FIG. 2, it can be seen that in embodiment, the support beam and the pull beam are spaced apart in a third direction Z, which is a height direction Z in this embodiment, so that after fixing the batteries in the receiving portion, the push beam applies a pushing force at the top and the pull beam applies a pulling force at the bottom. It should be understood that the pushing and pulling forces here are both forces F₁ and F₂ applied inward in the second direction Y, thereby fixing the battery in it. By spacing the support beam and the pull beam apart in the height direction Z, the force applied by the beam assembly towards the batteries is more uniform, thereby further enhancing the stability of the entire beam assembly structure. In addition, in another embodiment, the first pull beam 140, the second pull beam 141, the first support member 120, and the second support member can be spaced apart along the first direction X. Through this arrangement, the force applied by the beam assembly 100 towards the batteries can be more evenly distributed in the first direction X

In addition, the beam assembly 100 can be placed as a whole into the tray 200 before being connected to it, and then connected to the tray 200 through various methods such as welding, bonding, or screwing. When performing such operations, it is preferable to provide the edge of the push beam, for example, to have an installation slope inclined in the third direction Z, so that when the beam assembly 100 is incorporated into the tray 200, it can be installed more conveniently by sliding along with the contact between the installation slope and the side plates 201 of the tray. It can be understood that the support beam can also be provided with similar slope, so that during the installation process, the slope of the support beam can abut the end plates 202 of the tray and slide to achieve more convenient installation.

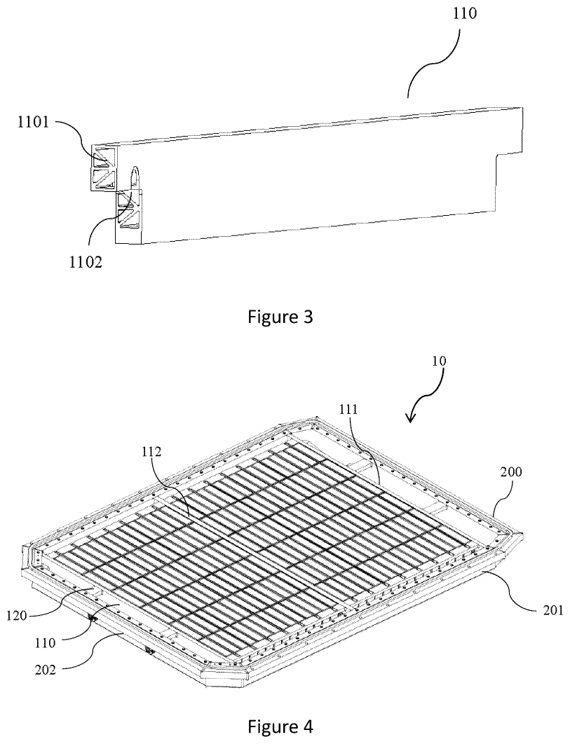

Referring to the schematic diagram of the push beam 110 of the beam assembly shown in FIG. 3, in this embodiment, the push beam 110 has a hollow structure, which includes multiple reinforcing portions 1101 extending laterally or diagonally. The reinforcing portions 1101 form a triangular and/or “ [symbol] ” shaped structure on the cross-section of the push beam 110. Through this arrangement, the lightweight of the push beam 110 is achieved while ensuring the structural strength of the push beam 110. It can be understood that the support member 120, the side rail 130, and the pull beam 140 in this embodiment also have the same or similar reinforcing portions as the push beam 110. And, other forms of reinforcing portions, such as reinforcing ribs extending in the direction of different beam structures in the beam assembly, can also be applied to different beam structures in the aforementioned beam assembly.

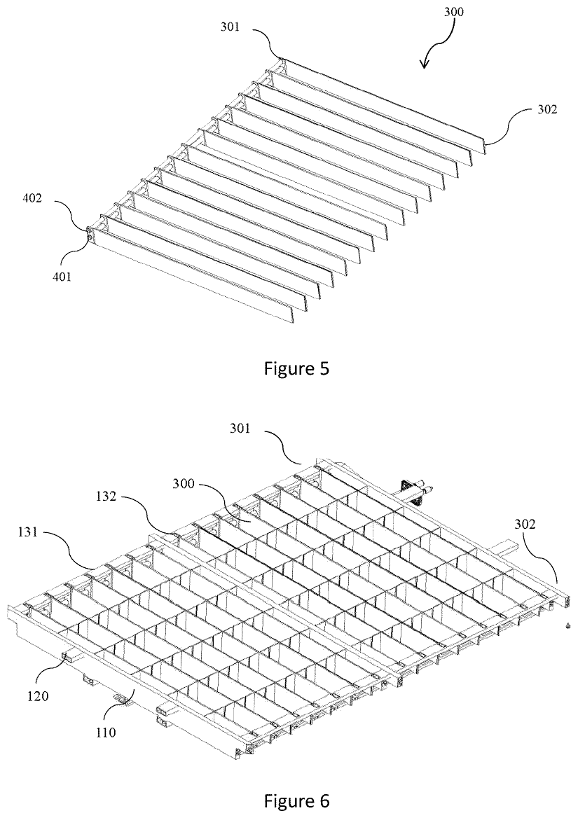

Continuing with reference to FIG. 3, one end of the push beam 110 has a groove 1102, it can be understood from the cooling structure shown in FIG. 5 that when the cooling structure shown in FIG. 5 is installed on the beam assembly 100, the groove 1102 is used to accommodate and define the position of an inlet pipe 401 or an outlet pipe 402 of a cooling plate 300.

Referring to FIG. 4, in the embodiment of the battery pack of the present disclosure, the battery pack 10 shown does not have a cover plate. The battery pack 10 has a tray 200, which includes a frame composed of side plates 201 and end plates 202. The battery pack 10 also includes the beam assembly 100 in the embodiments shown in FIGS. 1 to 3 above.

In the battery pack 10, multiple batteries are stacked along the second direction Y so that the largest surface of the multiple batteries can abut the cooling plate 300 extending along the first direction X to achieve effective heat dissipation. In the battery pack of this embodiment, multiple sets of batteries stacked along the second direction are respectively accommodated in the receiving portions A₁ and A₂. In the embodiment of the present disclosure, the stacked batteries are arranged upside down, that is, electrical connection components (such as poles) of multiple sets of stacked batteries are arranged towards a bottom wall of the tray 200. Each set of stacked batteries are electrically connected through a busbar located in grooves on multiple insulation boards on the bottom wall of the tray 200.

In this embodiment, when the batteries are stacked and arranged upside down in the receiving cavity formed by the tray 200 and the beam assembly 100, upper surfaces of adjacent batteries come into contact with the busbar located in the groove to achieve electrical connection between adjacent batteries. In the specific embodiment described, the busbar is at least partially accommodated in the groove, and both ends of the busbar extend out of the groove and are electrically connected to electrode terminals of the batteries. The groove can at least partially span two battery cells and the two battery cells are connected through the busbar located within it.

In this embodiment, the groove can at least partially span two sets of stacked batteries, completing the connection between the two sets of stacked batteries. The method of inverting the battery and relying on its own gravity to achieve a tight connection between the pole and the busbar thus simplifies the packaging process of battery pack 10, reduces the use of fasteners, and saves packaging costs. And this packaging method can also reduce the overall height of the battery pack 10, making it more suitable for power batteries in small and medium-sized vehicles.

Referring to the embodiment of the cooling plate shown in FIG. 5, multiple cooling plates 300 are connected together at their first end 301 through the inlet pipe 401 and the outlet pipe 402. In this embodiment, the first end 301 and a second end 302 of the cooling plates 300 are respectively installed between the first side rail 130 and the second side rail 131 through the mounting slots 132 on the first side rail 130 and the second side rail 131. The assembled state of the multiple cooling plates 300 and the beam assembly 100 is shown in the schematic diagram of FIG. 6. The multiple cooling plates 300 further separate the receiving portions A₁ and A₂, so that the cooling plates 300 can abut the battery cells in each set of stacked batteries along the second direction Y, thereby maximizing the contact surface between the cooling plate 300 and each battery cell in the battery to achieve better cooling effect. In addition, it can be seen from FIG. 6 that the receiving portion is separated by the cooling plate 300, and each two battery cells adjacent to each other along the first direction X are bonded by adhesives such as aerogel, while each battery cell is bonded to the cooling plate 300, so that the battery formed by the battery cells do not need additional fixing structures such as side plates, end plates, fasteners, etc. to fix them. Moreover, since each battery cell abuts at least one cooling plate 300, and the cooling plates 300 are fixed by the beam assembly 100, each battery cell can be clamped by the cooling plates 300, so that the expansion of each battery cell can be suppressed to a certain extent.

Technicians in this field can understand that “abut” in the description of the present disclosure refers to the contact between two or more components that do not have any other mechanical connection components, and are on direct contact or through non mechanical connection structures such as adhesives. In an embodiment of the present disclosure, during the assembly process, the beam assembly 100 is first placed in the tray 200, and then the cooling plate 300 after bonded and assembled with multiple batteries externally is assembled as a whole into the first side rail 130 and the second side rail 131 of the beam assembly 100, thereby completing the assembly of the batteries, the cooling plate 300, and the beam assembly 100.

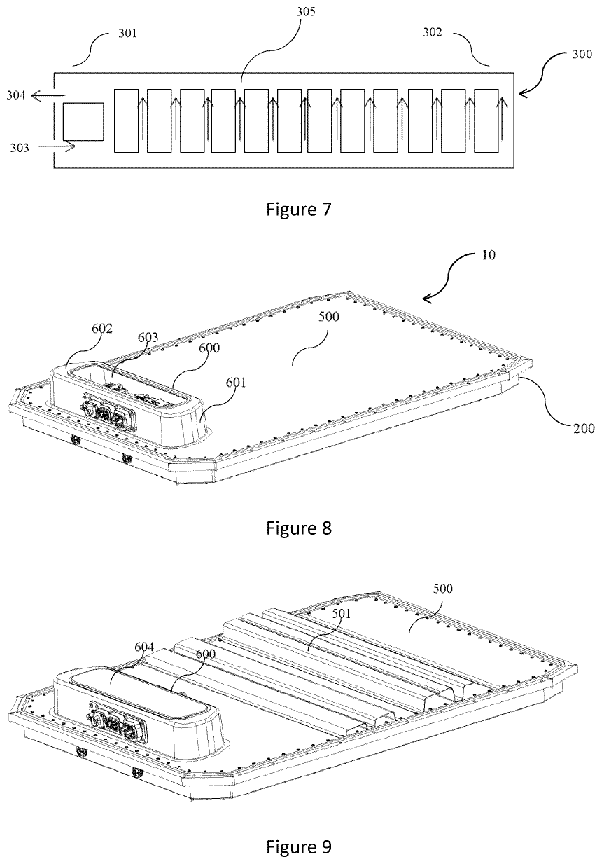

Referring to the cross-sectional view of the cooling plate 300 in the embodiment of the present invention in FIG. 7, the cooling plate 300 has an inlet manifold 303 and an outlet manifold 304, wherein the inlet manifold 303 is located below the outlet manifold 304 in the height direction Z, and the cooling plate 300 also includes multiple flow paths 305 located inside and extending in the height direction Z. The inlet pipe 401 has multiple inlet openings, and the outlet pipe 402 also has multiple outlet openings. When the inlet pipe 401 and the outlet pipe 402 are assembled with multiple cooling plates 300, the multiple inlet openings are respectively connected to the inlet manifold 303 of each cooling plate 300, and the multiple outlet openings are respectively connected to the outlet manifolds 304 of the multiple cooling plates 300.

When cooling the battery with coolant, the coolant enters the inlet manifold 303 through the inlet opening of the inlet pipe 401, flows from bottom to top through the flow path 305 inside the cooling plate 300, and finally discharges through the outlet manifold 304 to the outlet opening of the outlet pipe 402, achieving the circulation of coolant in the cooling plate 300. The battery in the embodiment of the present application is arranged upside down. During operation, due to the fact that the pole side of the battery in this embodiment of the present invention, which is the bottom side in this embodiment, has a higher temperature compared to the top side, the coolant can flow through the bottom first and then be discharged from the top, so that the bottom of the battery is cooled first, and the temperature of the coolant slightly increases before passing through the top, thereby reducing the temperature difference between the bottom and top of the battery and achieving more effective battery thermal management.

Continuing to refer to FIGS. 2 and 4, in the embodiment of the present disclosure, the first pull beam 140 and the second pull beam 141 abut and are fixed on the bottom plate of the tray 200. In this embodiment, the first pull beam 140 and the second pull beam 141 are bonded to the bottom plate of the tray 200 with adhesive. In this embodiment, the adhesive is structural adhesive; however, other types of adhesives can also be applied to the bonding between the pull beam and the bottom plate in the embodiment of the present invention. It can be understood that other connection methods, such as welding, fastener connections, etc., can also be used for the connection between the pull beam and the bottom plate of the tray. By fixing the pull beam to the bottom plate of the tray, the battery fixed by the beam assembly can be further stabilized, further enhancing the integration between the beam assembly and the tray, and also further reducing the noise caused by battery vibration during vehicle operation.

Referring to FIG. 8, a battery pack 10 packaged by a cover plate 500 according to an embodiment of the present disclosure is shown. In this embodiment, the cover plate 500 is connected to the tray 200 through fasteners. It can be understood that other connection methods can also be applied to the connection between the cover plate 500 and the tray 200. A seal is installed between the cover plate 500 and the tray 200 to ensure the sealing of the packaged battery pack 10. An opening is provided on the cover plate 500, which is sealed by an electrical housing 600. The electrical housing 600 includes a peripheral wall 601, a bottom wall (not shown in the figure), and an upper cover 602. The bottom wall of the electrical housing 600 covers and seals the opening to ensure the sealing of the battery pack 10. The upper cover 602 of the electrical housing 600 is provided with a window 603, and the electrical housing 600 accommodates electrical components of the battery pack 10. The electrical components pass through the bottom wall of the electrical housing 600 from the inside of the battery pack 10, and the electrical components and the bottom wall are sealed with a sealing material to ensure that external moisture or air cannot enter the interior of the battery pack 10 from the electrical housing 600. The window 603 can be detachably covered by a shutter 604 as shown in FIG. 9. The shutter 604 can be detachably connected to the upper cover 602 through various methods such as bonding, sliding, magnetic attraction, fasteners, etc., which facilitates maintenance and repair of the electrical components.

In addition, referring to FIG. 9, when the battery pack 10 is installed on the vehicle from below, the cover plate 500 of the battery pack 10 can serve as the floor of the vehicle, thereby increasing the height space of the vehicle and obtaining a flat floor inside the vehicle after the battery pack 10 is connected to the vehicle. When the cover plate 500 serves as the floor of the vehicle, multiple mounting parts 501 for installing vehicle components can be connected to the cover plate 500 through fasteners.

In an embodiment disclosed in the present disclosure, the battery pack 10 comprises a tray 200 and a beam assembly 100. The tray 200 comprises a bottom plate and a frame. The beam assembly 100 comprises a push beam. The push beam comprises a first push beam 110 and a second push beam 111 spaced apart. The first push beam 110 and the second push beam 111 extend along a first direction X and are connected to the tray 200 of the battery pack 10 to form a receiving portion between the first push beam 110 and the second push beam 111 for accommodating multiple batteries stacked along the second direction Y. The battery pack 10 also includes a support member. The support member includes a first support member 120 and a second support member. The first support member 120 and the second support member extend along the second direction Y and respectively connect the first push beam 110 and the second push beam 111 to the tray 200. The battery pack 10 also has a side rail, which include a first side rail 130 and a second side rail 131 spaced apart. The first side rail 130 and the second side rail 131 extend along the second direction Y and are connected to the first push beam 110 and the second push beam 111 from the ends of the first push beam 110 and the second push beam 111. In addition, the first side rail 130 and the second side rail 131 have multiple cooling plate mounting portions spaced apart, which in this embodiment are mounting slots 132. Multiple cooling plates 300 are installed along the first direction X through the multiple cooling plate mounting slots 132 and abut multiple batteries along the second direction Y. The battery pack 10 also has a cover plate 500, which is sealingly connected to the tray 200. The cover plate 500 contains an opening, which is covered and sealed by the electrical housing 600. The electrical housing 600 accommodates the electrical components of the battery pack 10 and has a detachable window for convenient maintenance and repair of the electrical components.

Exemplary embodiments of the present disclosure also proposes a motor vehicle using the battery pack 10 described above, including but not limited to pure electric vehicles (BEVs), hybrid electric vehicles (HEVs), and plug-in hybrid electric vehicles (PHEVs).

In this application, the use of the disjunctive is intended to include the conjunctive. The use of definite or indefinite articles is not intended to indicate cardinality. In particular, a reference to “the” object or “a” and “an” object is intended to denote also one of a possible plurality of such objects. Further, the conjunction “or” may be used to convey features that are simultaneously present instead of mutually exclusive alternatives. In other words, the conjunction “or” should be understood to include “and/or”. The terms “includes,” “including,” and “include” are inclusive and have the same scope as “comprises,” “comprising,” and “comprise” respectively.

The preceding description is exemplary rather than limiting in nature. Variations and modifications to the disclosed examples may become apparent to those skilled in the art that do not necessarily depart from the essence of this disclosure. Thus, the scope of protection given to this disclosure can only be determined by studying the following claims.

What is claimed is:

1. A beam assembly for a battery pack, comprising:
at least one push beam that extends along a first direction and is connected to a tray of the battery pack;
at least one support member that extends along a second direction and connects the at least one push beam to the tray; and
at least one side rail that extends along the second direction and is connected to the at least one push beam from an end of the at least one push beam, the at least one side rail having a plurality of cooling plate mounting portions spaced apart from each other.

2. The beam assembly according to claim 1, wherein the at least one push beam comprises a first push beam and a second push beam that are spaced apart and have ends that are respectively connected to the tray, wherein a receiving portion is formed between the first push beam and the second push beam.

3. The beam assembly according to claim 1, wherein the at least one support member comprises a first support member and a second support member that respectively connect the at least one push beam to the tray in the second direction.

4. The beam assembly according to claim 2, wherein the at least one push beam further comprises:
a third push beam that extends along the first direction and is spaced apart from the first push beam and the second push beam, wherein ends of the third push beam are connected to the tray in the first direction to divide the receiving portion into a first receiving portion and a second receiving portion.

5. The beam assembly according to claim 2, wherein the at least one side rail comprises a first side rail and a second side rail that are spaced apart from each other, extend along the second direction, and are respectively connected to the first push beam and the second push beam from ends of the first push beam and the second push beam.

6. The beam assembly according to claim 5, wherein the plurality of cooling plate mounting portions include a plurality of mounting slots, the plurality of mounting slots recessed along the first direction and spaced apart along the second direction, the plurality of mounting slots on the first side rail and the second side rail are arranged opposite to each other.

7. The beam assembly according to claim 2, further comprising:
at least one pull beam that extends along the second direction and is respectively connected to the first push beam and the second push beam.

8. The beam assembly according to claim 7, wherein the at least one support member is spaced apart from the at least one pull beam in a third direction, wherein the third direction is a height direction.

9. The beam assembly according to claim 8, wherein the at least one pull beam comprises a first pull beam and a second pull beam, and wherein the at least one support member comprises a first support member and a second support member that are spaced apart from the first pull beam and the second pull beam along the first direction.

10. A battery pack, comprising:
a tray comprising a bottom plate and a frame;
a beam assembly comprising:
at least one push beam that extends along a first direction and is connected to the tray of the battery pack;
at least one support member that extends along a second direction and connects the at least one push beam to the tray;
at least one side rail that extends along the second direction and is connected to the at least one push beam from an end of the at least one push beam, the at least one side rail having a plurality of cooling plate mounting portions spaced apart from each other; and
a cover plate that is sealingly connected to the tray.

11. The battery pack according to claim 10, wherein the at least one push beam comprises a first push beam and a second push beam that are spaced apart and respectively connected at their ends to the tray, wherein a receiving portion is formed between the first push beam and the second push beam to accommodate batteries.

12. The battery pack according to claim 11, wherein the at least one side rail comprises a first side rail and a second side rail that are spaced apart from each other, extend along the second direction, and are respectively connected to the first push beam and the second push beam from ends of the first push beam and the second push beam.

13. The battery pack according to claim 12, wherein the plurality of cooling plate mounting portions comprise a plurality of mounting slots, wherein the plurality of mounting slots are recessed along the first direction and spaced apart along the second direction, and the plurality of mounting slots on the first side rail and the second side rail are arranged opposite to each other;
multiple cooling plates are installed along the first direction through the plurality of mounting slots and abut a plurality of batteries along the second direction.

14. The battery pack according to claim 13, further comprising a cooling pipe that extends along the second direction between one end of the at least one push beam and the tray and comprises an inlet pipe having a plurality of inlet openings and an outlet pipe having a plurality of outlet openings.

15. The battery pack according to claim 14, wherein each of the plurality of inlet openings of the inlet pipe is respectively connected to an inlet manifold of each cooling plate, and each of the plurality of outlet openings of the outlet pipe is respectively connected to an outlet manifold of each cooling plate; and each cooling plate has multiple paths extending along the first direction and a third direction, which is a height direction.

16. The battery pack according to claim 15, wherein the inlet pipe and the outlet pipe are spaced apart and parallel to each other in the third direction and the inlet pipe is arranged below the outlet pipe.

17. The battery pack according to claim 11, further comprising: at least one pull beam that extends along the second direction and is respectively connected to the first push beam and the second push beam, wherein the at least one support member is spaced apart from the at least one pull beam in a third direction, the third direction a height direction.

18. The battery pack according to claim 17, wherein the at least one pull beam has a lower surface that abuts the bottom plate of the tray and is connected to the bottom plate.

19. The battery pack according to claim 10, wherein the cover plate comprises an opening that is covered and sealed by an electrical housing, and the electrical housing accommodates electrical components of the battery pack and has a detachable window.

20. A battery pack, comprising:
a tray comprising a bottom plate and a frame;
a beam assembly comprising:
at least one push beam comprising a first push beam and a second push beam that is spaced apart, extend along a first direction and is connected to the tray of the battery pack to form a receiving portion between the first push beam and the second push beam for accommodating a plurality of batteries stacked along a second direction;
at least one support member comprising a first support member and a second support member that extend along the second direction and respectively connect the first push beam and the second push beam to the tray;
at least one side rail comprising a first side rail and a second side rail that is spaced apart, extend along the second direction, and is connected to the first push beam and the second push beam from ends of the first push beam and the second push beam,
wherein the at least one side rail has a plurality of cooling plate mounting portions spaced apart from each other, wherein a plurality of cooling plates are installed along the first direction through a plurality of mounting slots to abut multiple batteries along the second direction; and
a cover plate that is sealingly connected to the tray,
wherein the cover plate comprises an opening that is covered and sealed by an electrical housing, and the electrical housing accommodates electrical components of the battery pack and has a detachable window.
